(19) United States
(12) Patent Application Publication
(10) Pub. No.: US 2026/0040743 A1
(43) Pub. Date: Feb. 5, 2026

(54) DISPLAY DEVICE

(71) Applicant: Samsung Display Co., LTD., Yongin-si (KR)

(72) Inventors: Young Gu KANG, Yongin-si (KR); Min Ji KIM, Yongin-si (KR); Hyeon Do PARK, Yongin-si (KR); Hyun Sung PARK, Yongin-si (KR); Dong Jin SEO, Yongin-si (KR); Yu Jin CHOI, Yongin-si (KR)

(73) Assignee: Samsung Display Co., LTD., Yongin-si (KR)

(21) Appl. No.: 19/075,002

(22) Filed: Mar. 10, 2025

(30) Foreign Application Priority Data
Aug. 5, 2024 (KR) 10-2024-0103554

(51) Int. Cl. H10H 29/39; H10H 29/32; H10K 59/121; H10K 59/123

(52) U.S. Cl. CPC H10H 29/39; H10H 29/32; H10K 59/1213; H10K 59/123

(57) ABSTRACT

A display device includes a first pixel including a first light-emitting element emitting light of a first color, and a first transistor that provides a driving current to the first light-emitting element and including a semiconductor region extending in a first direction, a second pixel including a second light-emitting element emitting light of a second color different from the first color, and a second transistor that provides a driving current to the second light-emitting element and including a semiconductor region, a first metal layer under the first transistor and overlapping the semiconductor region of the first transistor, and a second metal layer under the second transistor and overlapping the semiconductor region of the second transistor.

### CROSS-REFERENCE TO RELATED APPLICATION(S)

This application claims priority to and benefits of Korean Patent Application No. 10-2024-0103554 under 35 U.S.C. § 119, filed on Aug. 5, 2024, in the Korean Intellectual Property Office (KIPO), the entire contents of which are incorporated herein by reference.

### BACKGROUND

### 1. Technical Field

Embodiments relate to a display device.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions. A display device, in which each of the pixels of the display panel includes a light-emitting element that emits light by itself, may display images without a backlight unit that supplies light to the display panel.

The display device includes pixels, data lines and gate lines connected to the pixels, a data driver that supplies data voltages to the data lines, and a gate driver that supplies gate signals to the gate lines. The data driver and the gate driver may drive the pixels at a selected frequency.

### SUMMARY

Embodiments provide a display device capable of improving the issue of afterimage.

However, embodiments are not limited to those set forth herein. The above and other embodiments will be apparent to one of ordinary skill in the art to which the disclosure pertains by referencing the detailed description of the disclosure given below.

According to an embodiment, a display device includes a first pixel including a first light-emitting element emitting light of a first color, and a first transistor that provides a driving current to the first light-emitting element and including a semiconductor region extending in a first direction, a second pixel including a second light-emitting element emitting light of a second color different from the first color, and a second transistor that provides a driving current to the second light-emitting element and including a semiconductor region, a first metal layer disposed under the first transistor and overlapping the semiconductor region of the first transistor, and a second metal layer disposed under the second transistor and overlapping the semiconductor region of the second transistor. A first distance between a first side of the first metal layer and the semiconductor region of the first transistor in a second direction intersecting the first direction is greater than a second distance between a first side of the second metal layer corresponding to the first side of the first metal layer and the semiconductor region of the second transistor.

The semiconductor region of the first transistor may have a straight line shape extending in the first direction, and the semiconductor region of the second transistor may have a shape that is bent at least once.

The first distance may be substantially equal to or greater than twice the second distance.

The first color may be blue, and the second color may be red or green.

The first metal layer may include a first portion overlapping the semiconductor region of the first transistor, a second portion extending from the first portion in the first direction and connected to the second metal layer, and a third portion extending from the first portion in the second direction.

A first width of a gate electrode of the first transistor in the first direction may be smaller than a second width of the first portion of the first metal layer in the first direction.

The entire semiconductor region of the first transistor may overlap the first portion of the first metal layer.

A first width of a gate electrode of the first transistor in the first direction may be greater than a second width of the first portion of the first metal layer in the first direction.

A central portion of the semiconductor region of the first transistor may overlap the first portion of the first metal layer. Edge portions of the semiconductor region of the first transistor may not overlap the first metal layer.

The first pixel further may include a third transistor that applies a data voltage to a first electrode of the first transistor, a fourth transistor that electrically connects a second electrode of the first transistor with a gate electrode of the first transistor, a fifth transistor that electrically connects the gate electrode of the first transistor with a first initialization voltage line, and a capacitor connected between a driving voltage line supplying a driving voltage and the gate electrode of the first transistor.

The display device may further include a first active layer disposed on the first metal layer and including a semiconductor region of the first transistor, a first gate layer disposed on the first active layer and including a first capacitor electrode of the capacitor, a second gate layer disposed on the first gate layer and including a second capacitor electrode of the capacitor, a second active layer disposed on the second gate layer and including a semiconductor region of the fourth transistor, and a third gate layer disposed on the second active layer and including a gate electrode of the fourth transistor.

According to an embodiment, an electronic device includes: a display device including a first pixel including a first light-emitting element and a first transistor that provides a driving current to the first light-emitting element and including a semiconductor region, a second pixel including a second light-emitting element and a second transistor that provides a driving current to the second light-emitting element and including a semiconductor region, a first metal layer disposed under the first transistor and overlapping the semiconductor region of the first transistor, and a second metal layer disposed under the second transistor and overlapping the semiconductor region of the second transistor. The semiconductor region of the first transistor is closer to a lower edge portion than an upper edge portion of a gate electrode of the first transistor.

The semiconductor region of the first transistor may have a straight line shape extending in a first direction, and the semiconductor region of the second transistor may have a shape that is bent at least once.

A first distance between an upper side of the first metal layer and the semiconductor region of the first transistor in a second direction intersecting the first direction may be greater than a second distance between an upper side of the second metal layer and the semiconductor region of the second transistor in the second direction.

The first metal layer may include a first portion overlapping the semiconductor region of the first transistor, a second portion extending from the first portion in the first direction and connected to the second metal layer, and a third portion extending from the first portion in the second direction.

A first width of a gate electrode of the first transistor in the first direction may be smaller than a second width of the first portion of the first metal layer in the first direction.

The entire semiconductor region of the first transistor may overlap the first portion of the first metal layer.

A first width of a gate electrode of the first transistor in the first direction may be greater than a second width of the first portion of the first metal layer in the first direction.

A central portion of the semiconductor region of the first transistor may overlap the first portion of the first metal layer. Edge portions of the semiconductor region of the first transistor may not overlap the first metal layer.

The first light-emitting element may emit blue light, and the second light-emitting element may emit red light or green light.

According to embodiments, a semiconductor region of a first transistor is adjacent to the central portion of a metal layer, so that an electric field and static electricity applied to the first transistor may be blocked, and the issue of afterimage may be improved.

### BRIEF DESCRIPTION OF THE DRAWINGS

The accompanying drawings, which are included to provide a further understanding of the disclosure, illustrate embodiments in which:

FIG. 1 is a schematic perspective view showing a display device according to an embodiment.

FIG. 2 is a schematic cross-sectional view showing a display device according to an embodiment.

FIG. 3 is a schematic plan view showing a display unit of a display device according to an embodiment.

FIG. 4 is a schematic block diagram illustrating the display panel and the display driver according to an embodiment.

FIG. 5 is a schematic diagram of an equivalent circuit of a pixel of a display device according to an embodiment.

FIG. 6 is a schematic cross-sectional view showing a pixel in a display device according to an embodiment.

FIG. 7 is a schematic plan view showing metal layers and first active layers of first to third pixels in a display device according to an embodiment.

FIG. 8 is a schematic plan view showing a metal layer, a first active layer and a first gate layer of the first pixel in the display device according to an embodiment.

FIG. 9 is a schematic plan view showing a metal layer, a first active layer and a first gate layer of each of the second and third pixels in the display device according to an embodiment.

FIG. 10 is a schematic plan view showing metal layers and first active layers of first to third pixels in a display device according to another embodiment.

FIG. 11 is a schematic plan view showing a metal layer, a first active layer and a first gate layer of the first pixel in the display device according to the another embodiment.

FIG. 12 is a schematic plan view showing a metal layer, a first active layer and a first gate layer of each of the second and third pixels in the display device according to the another embodiment.

FIGS. 13 and 14 are schematic perspective views illustrating application examples of electronic devices.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Each of the features of the various embodiments of the invention may be partially or wholly combined or combined with each other, and various technical connections and operations are possible, and each embodiment may be implemented independently of each other or may be implemented together in a related relationship. Specific embodiments will be described below with reference to the attached drawings.

Hereinafter, embodiments will be described in detail with reference to the accompanying drawings.

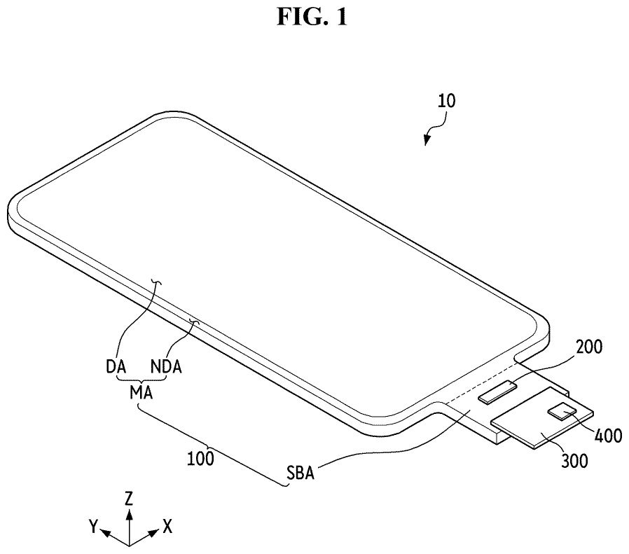

FIG. 1 is a schematic perspective view showing a display device according to an embodiment.

Referring to FIG. 1, a display device 10 may be employed (or implemented) by portable electronic devices such as a mobile phone, a smart phone, a tablet PC, a mobile communications terminal, an electronic notebook, an electronic book, a portable multimedia player (PMP), a navigation device and an ultra mobile PC (UMPC). For example, the display device 10 may be used as a display unit of a television, a laptop computer, a monitor, an electronic billboard, or the Internet of Things (IOT). For another example, the display device 10 may be applied to wearable devices such as a smart watch, a watch phone, a glasses-type display, and a head-mounted display (HMD) device.

The display device 10 may have a shape similarly to a quadrangular shape when viewed from the top (or in plan view). For example, the display device 10 may have a shape similar to a rectangle having shorter sides in the x-axis direction and longer sides in the y-axis direction when viewed from the top (or in plan view). The corners where the shorter sides in the x-axis direction and the longer sides in the y-axis direction meet may be rounded to have a selected curvature or may be formed at a right angle. The shape of the display device 10 when viewed from the top (or in plan view) is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA.

The main area MA may include a display area DA having pixels for displaying images, and a non-display area NDA disposed around the display area DA. The display area DA may output lights from emission areas or open areas. For example, the display panel 100 may include a pixel circuit including switching elements, a pixel-defining layer that defines the emission areas or the open areas, and self-light-emitting elements.

For example, the self-light-emitting element may include one of: an organic light-emitting diode including an organic light-emitting layer, a quantum-dot light-emitting diode (quantum LED) including a quantum-dot emissive layer, an inorganic light-emitting diode (inorganic LED) including an inorganic semiconductor, and a micro light-emitting diode (micro LED). However, embodiments are not limited thereto.

The non-display area NDA may be disposed on the outer side of the display area DA. The non-display area NDA may be defined as the edge portion of the main area MA of the display panel 100. The non-display area NDA may include a gate driver that applies gate signals to gate lines, and fan-out lines that connect the display driver 200 with the display area DA.

The subsidiary area SBA may extend from a side of the main area MA. The subsidiary area SBA may include a flexible material that is bendable, foldable, or rollable. For example, in case that the subsidiary area SBA is bent, the subsidiary area SBA may overlap the main area MA in the thickness direction (e.g., z-axis direction). The subsidiary area SBA may include pads connected to the display driver 200 and the circuit board 300. In another example, the subsidiary area SBA may be eliminated, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be disposed in the subsidiary area SBA and may overlap the main area MA in the thickness direction (e.g., z-axis direction) as the subsidiary area SBA is bent. For another example, the display driver 200 may be mounted on the circuit board 300.

The circuit board 300 may be attached on the pad area of the display panel 100 using an anisotropic conductive film (ACF). Lead lines of the circuit board 300 may be electrically connected to the pads of the display panel 100. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be electrically connected to a touch sensing unit of the display panel 100. The touch driver 400 may supply a touch driving signal to touch electrodes of the touch sensing unit and may sense a change in the capacitance between the touch electrodes. For example, the touch driving signals may be pulse signals having a selected frequency. The touch driver 400 may determine whether there is an input and may find the coordinates of the input based on the amount of the change in the capacitance between the touch electrodes. The touch driver 400 may be implemented as an integrated circuit (IC).

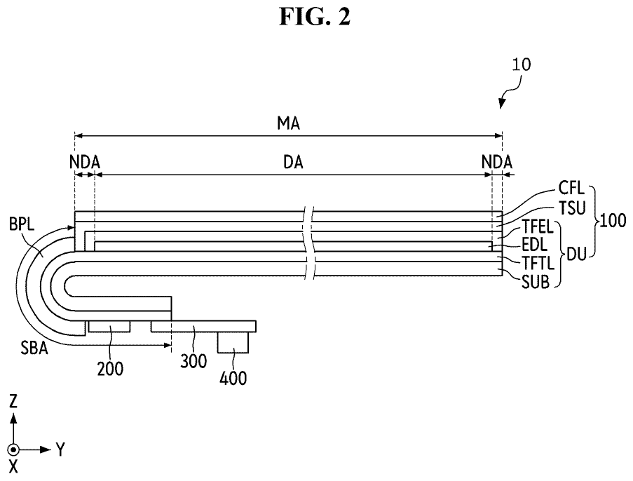

FIG. 2 is a schematic cross-sectional view showing a display device according to an embodiment.

Referring to FIG. 2, the display panel 100 may include a display unit DU, a touch sensing unit TSU, and a color filter layer CFL. The display unit DU may include a substrate SUB, a transistor layer TFTL, an emission material layer EDL and an encapsulation layer TFEL.

The substrate SUB may be a base substrate or a base member. The substrate SUB may be a flexible substrate that is bendable, foldable, or rollable. For example, the substrate SUB may include a polymer resin such as polyimide PI. However, embodiments are not limited thereto. For another example, the substrate SUB may include a glass material or a metal material.

The transistor layer TFTL may be disposed on the substrate SUB. The transistor layer TFTL may include thin-film transistors forming pixel circuits of pixels. The transistor layer TFTL may include gate lines, data lines, voltage lines, gate control lines, fan-out lines for connecting the display driver 200 with the data lines, lead lines for connecting the display driver 200 with the pads, etc. Each of the thin-film transistors may include a semiconductor region, a source electrode, a drain electrode, and a gate electrode. For example, in case that the gate driver is formed on a side of the non-display area NDA of the display panel 100, the gate driver may include thin-film transistors.

The transistor layer TFTL may be disposed in the display area DA, the non-display area NDA and the subsidiary area SBA. The thin-film transistors in each of the pixels, the gate lines, the data lines and the voltage lines in the transistor layer TFTL may be disposed in the display area DA. The gate control lines and the fan-out lines in the transistor layer TFTL may be disposed in the non-display area NDA. The lead lines of the transistor layer TFTL may be disposed in the subsidiary area SBA.

The emission material layer EDL may be disposed on the transistor layer TFTL. The emission material layer EDL may include light-emitting elements in each of which a pixel electrode, an emissive layer and a common electrode are stacked on one another sequentially to emit light, and a pixel-defining film for defining the pixels. The light-emitting elements in the emission material layer EDL may be disposed in the display area DA.

For example, the emissive layer may be an organic light-emitting layer containing an organic material. The emissive layer may include a hole transporting layer, an organic light-emitting layer and an electron transporting layer. In case that the pixel electrode receives a voltage and the common electrode receives a cathode voltage through the thin-film transistors in the thin-film transistor layer TFTL, holes may move (or transfer) to the organic light-emitting layer through the hole transporting layer and electrons may move (or transfer) to the organic light-emitting layer through the electron transporting layer, such that the holes and the electrons may combine in the organic light-emitting layer to emit light. For example, the pixel electrode may be an anode electrode, and the common electrode may be a cathode electrode. It is, however, to be understood that the disclosure is not limited thereto.

As another example, the light-emitting elements may include quantum-dot light-emitting diodes each including a quantum-dot emissive layer, inorganic light-emitting diodes each including an inorganic semiconductor, or micro light-emitting diodes.

The encapsulation layer TFEL may cover the upper and side surfaces of the emission material layer EDL, and may protect the emission material layer EDL. The encapsulation layer TFEL may include at least one inorganic layer and at least one organic layer for encapsulating the emission material layer EDL.

The touch sensing unit TSU may be disposed on the encapsulation layer TFEL. The touch sensing unit TSU may include touch electrodes for sensing a user's touch by a capacitive sensing method, and touch lines connecting the touch electrodes with the touch driver 400. For example, the touch sensing unit TSU may sense a user's touch by a mutual capacitance sensing method or a self-capacitance sensing method.

For another example, the touch sensing unit TSU may be disposed on a separate substrate disposed on the display unit DU. For example, the substrate supporting the touch sensing unit TSU may be an encapsulation substrate that encapsulates the display unit DU.

The touch electrodes of the touch sensing unit TSU may be disposed in a touch sensor area overlapping the display area DA. The touch lines of the touch sensing unit TSU may be disposed in a touch peripheral area overlapping the non-display area NDA.

The color filter layer CFL may be disposed on the touch sensing unit TSU. The color filter layer CFL may include color filters associated with the emission areas, respectively. Each of the color filters may selectively transmit light of a particular wavelength and block or absorb lights of other wavelengths. The color filter layer CFL may absorb some of lights introduced from the outside of the display device 10 to reduce the reflection of external light. Accordingly, the color filter layer CFL may prevent distortion of colors due to the reflection of external light.

Since the color filter layer CFL is disposed (e.g., directly disposed) on the touch sensing unit TSU, the display device 10 may require no separate substrate for the color filter layer CFL. Therefore, the thickness of the display device 10 may be relatively reduced.

The subsidiary area SBA of the display panel 100 may extend from a side of the main area MA. The subsidiary area SBA may include a flexible material that is bendable, foldable, or rollable. For example, in case that the subsidiary area SBA is bent, the subsidiary area SBA may overlap the main area MA in the thickness direction (e.g., z-axis direction). The subsidiary area SBA may include pads electrically connected to the display driver 200 and the circuit board 300.

The display device 10 may include a bending protection layer BPL that protects the subsidiary area SBA. The bending protection layer BPL may be disposed on the transistor layer TFTL of the bent subsidiary area SBA. The bending protection layer BPL may protect the transistor layer TFTL of the bent subsidiary area SBA and reduce tensile stress of the subsidiary area SBA.

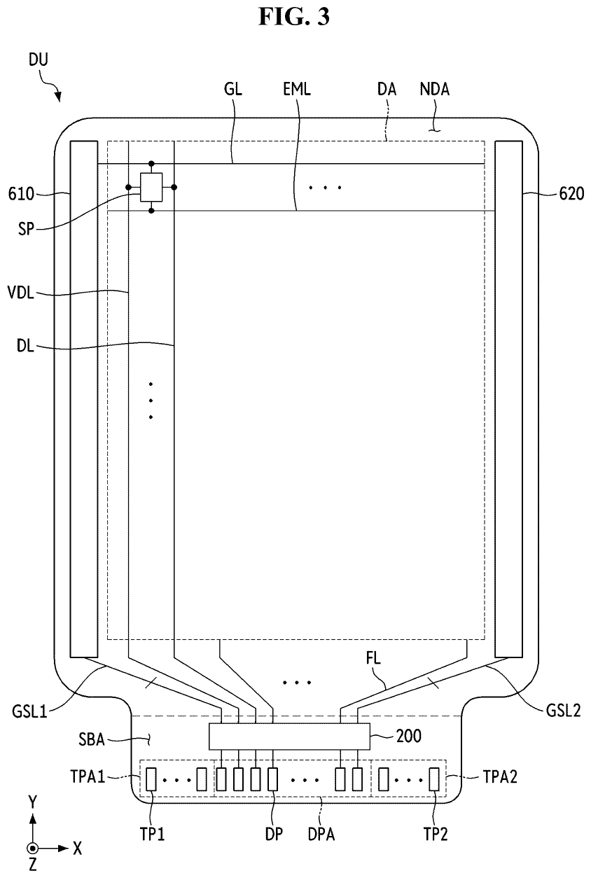

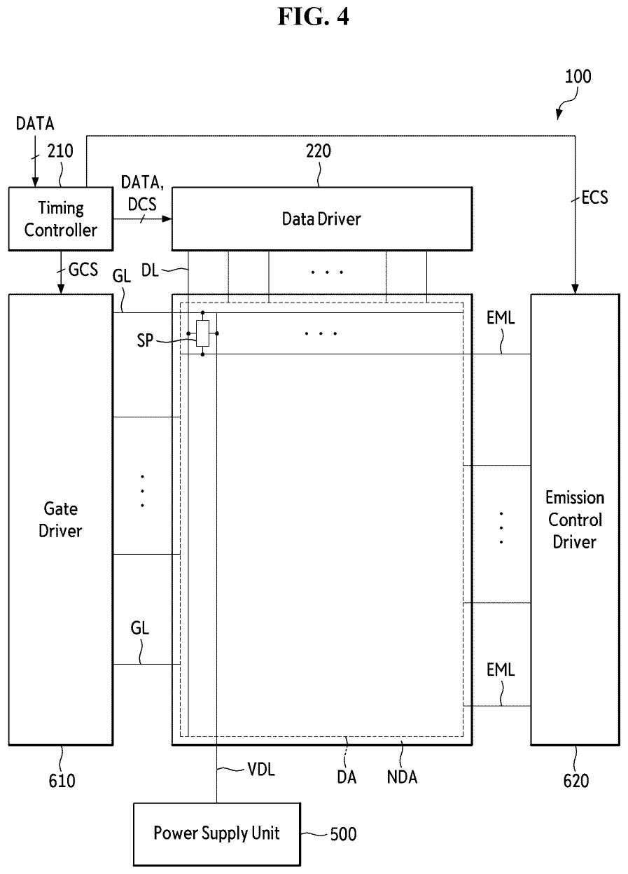

FIG. 3 is a schematic plan view showing the display unit of the display device according to an embodiment. FIG. 4 is a block diagram illustrating the display panel and the display driver according to an embodiment.

Referring to FIGS. 3 and 4, the display panel 100 may include the display area DA and the non-display area NDA. The display area DA may include pixels SP, supply voltage lines VDL, gate lines GL, emission control lines EML, and data lines DL.

Each of the pixels SP may be connected to a gate line GL, a data line DL, an emission control line EML, and a supply voltage line VDL. Each of the pixels SP may include a transistor, a light-emitting element, and a capacitor.

The gate lines GL may extend in the x-axis direction and may be spaced apart from one another in the y-axis direction intersecting the x-axis direction. The gate lines GL may sequentially supply gate signals to the pixels SP.

The emission control lines EML may extend in the x-axis direction and may be spaced apart from each other in the y-axis direction. The emission control lines EML may sequentially supply emission signals to the pixels SP.

The data lines DL may extend in the y-axis direction and may be spaced apart from one another in the x-axis direction. The data lines DL may provide data voltage to the pixels SP. The data voltage may determine the brightness of each of the pixels SP.

The supply voltage lines VDL may extend in the y-axis direction and may be spaced apart from one another in the x-axis direction. The supply voltage lines VDL may supply driving voltages to the pixels SP. The driving voltages may be high-level voltages for driving the light-emitting elements of the pixels SP.

The non-display area NDA may surround the display area DA. The non-display area NDA may include a gate driver 610, an emission control driver 620, fan-out lines FL, a first gate control line GSL1 and a second gate control line GSL2.

The fan-out lines FL may extend from the display driver 200 to the display area DA. The fan-out lines FL may supply the data voltage received from the display driver 200 to the data lines DL. The fan-out lines FL may supply the driving voltages received from the display driver 200 to the supply voltage lines VDL.

The first gate control line GSL1 may extend from the display driver 200 to the gate driver 610. The first gate control line GSL1 may supply the gate control signal GCS received from the display driver 200 to the gate driver 610.

The second gate control line GSL2 may extend from the display driver 200 to the emission control driver 620. The second gate control line GSL2 may provide an emission control signal ECS received from the display driver 200 to the emission control driver 620.

The subsidiary area SBA may extend from a side of the non-display area NDA. The subsidiary area SBA may include the display driver 200, a display pad area DPA, and first and second touch pad areas TPA1 and TPA2.

The display driver 200 may include a timing controller 210 and a data driver 220.

The timing controller 210 may receive digital video data DATA and timing signals from the circuit board 300. The timing controller 210 may generate a data control signal DCS to control the operation timing of the data driver 220, may generate a gate control signal GCS to control the operation timing of the gate driver 610, and may generate an emission control signal ECS to control the operation timing of the emission control driver 620 based on the timing signals. The timing controller 210 may supply the gate control signal GCS to the gate driver 610 through the first gate control line GSL1. The timing controller 210 may provide the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and may supply them to the data lines DL through the fan-out lines FL. The gate signals of the gate driver 610 may be used to select pixels SP to which data voltages are applied, and the selected pixels SP may receive the data voltages through the data lines DL.

The display pad area DPA, the first touch pad area TPA1 and the second touch pad area TPA2 may be disposed on the edge portion of the subsidiary area SBA. The display pad area PA, the first touch pad area TPA1 and the second touch pad area TPA2 may be electrically connected to the circuit board 300 using a low-resistance, high-reliable material such as an anisotropic conductive film and a self assembly anisotropic conductive paste (SAP).

The display pad area DPA may include display pads DP. The display pads DP may be electrically connected to a graphic system through the circuit board 300. The display pads DP may be connected to the circuit board 300 to receive digital video data and may supply the digital video data to the display driver 200. The display pads DP may provide timing signals to the display driver 200.

The first touch pad area TPA1 may be disposed on a side of the display pad area DPA and may include first touch pads TP1. The first touch pads TP1 may be electrically connected to the touch driver 400 disposed on the circuit board 300. The first touch pads TP1 may supply touch driving signals to driving electrodes through driving lines.

The second touch pad area TPA2 may be disposed on the opposite side of the display pad area DPA and may include second touch pads TP2. The second touch pads TP2 may be electrically connected to the touch driver 400 disposed on the circuit board 300. The touch driver 400 may receive a touch sensing signal through sensing lines connected to the second touch pads TP2, and may sense a change in the capacitance between the driving electrodes and sensing electrodes.

A power supply unit 500 may apply supply voltages to the display driver 200 and the display panel 100. The power supply unit 500 may generate a driving voltage to supply it to the driving voltage line VDL, and may generate a common voltage to supply it to a common electrode shared by the light-emitting elements of pixels SP. The power supply unit 500 may generate an initialization voltage to supply it to the initialization voltage line, may generate a reference voltage to supply it to a reference voltage line, and may generate a bias voltage to supply it to a bias voltage line.

The gate driver 610 may be disposed on an outer side of the display area DA or on an outer side of the non-display area NDA, and the emission control driver 620 may be disposed on the opposite outer side of the display area DA or on the opposite outer side of the non-display area NDA. It should be understood, however, that the disclosure is not limited thereto. For another example, the gate driver 610 and the emission control driver 620 may be disposed on a side or the opposite side of the non-display area NDA.

The gate driver 610 may include thin-film transistors for generating gate signals based on the gate control signal GCS. The emission control driver 620 may include thin-film transistors for generating emission signals based on the emission control signal ECS. For example, the transistors of the gate driver 610 and the transistors of the emission control driver 620 may be formed in the same layer as the transistors of the pixels SP. The gate driver 610 may provide gate signals to the gate lines GL, and the emission control driver 620 may provide emission signals to the emission control lines EML.

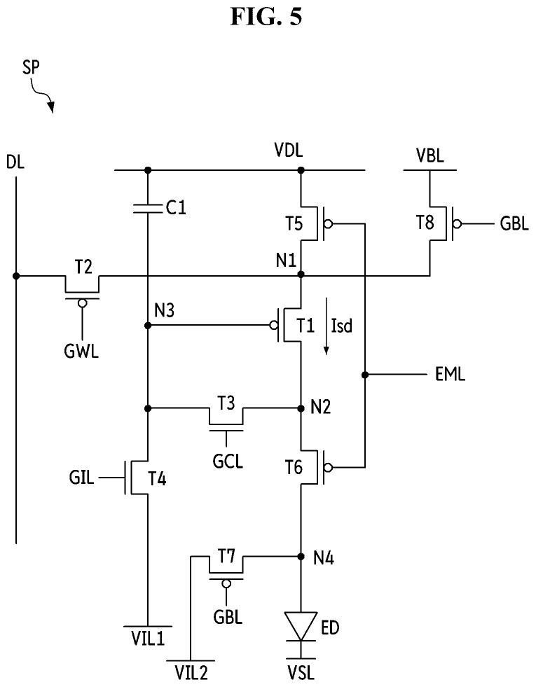

FIG. 5 is a schematic diagram of an equivalent circuit of a pixel of a display device according to an embodiment.

Referring to FIG. 5, the display panel 100 may include pixels SP arranged in rows and columns. Each of the pixels SP may be connected to a first gate line GWL, a second gate line GCL, a third gate line GIL, a fourth gate line GBL, an emission control line EML, a data line DL, a supply voltage line VDL, a first initialization voltage line VIL1, a second initialization voltage line VIL2, a bias voltage line VBL, and a low-level voltage line VSL.

The pixel SP may include a light-emitting element ED and a pixel circuit that drives the light-emitting element ED. The pixel circuit may include first to eighth transistors T1, T2, T3, T4, T5, T6, T7 and T8, and a capacitor C1.

The first transistor T1 may control a driving current supplied to the light-emitting element ED. The first transistor T1 may include a gate electrode, a first electrode, and a second electrode. The gate electrode of the first transistor T1 may be connected to a third node N3, the first electrode of the first transistor T1 may be connected to a first node N1, and the second electrode of the first transistor T1 may be connected to a second node N2. For example, the first electrode of the first transistor T1 may be the source electrode while the second electrode may be the drain electrode. It is, however, to be understood that the disclosure is not limited thereto.

The first transistor T1 may control the source-drain current Isd (hereinafter, referred to as “driving current”) according to the data voltage applied to the gate electrode. The driving current Isd flowing through the channel of the first transistor T1 may be proportional to the square of the difference between the threshold voltage Vth and the voltage Vsg between the source electrode and the gate electrode of the first transistor T1 (Isd=k′×(Vsg−Vth)²) where k denotes a proportional coefficient determined by the structure and physical properties of the first transistor T1, Vsg denotes the source-gate voltage of the first transistor T1, and Vth denotes the threshold voltage of the first transistor T1.

The light-emitting element ED may receive the driving current Isd to emit light. The amount or the luminance of the light emitted from the light-emitting element ED may be proportional to the magnitude of the driving current Isd. The light-emitting element ED may include a first electrode, a second electrode, and an emissive layer disposed between the first electrode and the second electrode. The first electrode of the light-emitting element ED may be connected to a fourth node N4. The first electrode of the light-emitting element ED may be electrically connected to the second electrode of the sixth transistor T6 and the first electrode of the seventh transistor T7 through the fourth node N4. The second electrode of the light-emitting element ED may be electrically connected to the low-level voltage line VSL and may receive a low-level voltage from the low-level voltage line VSL. For example, the first electrode of the light-emitting element ED may be an anode electrode or a pixel electrode, while the second electrode of the light-emitting element ED may be a cathode electrode or a common electrode. It is, however, to be understood that the disclosure is not limited thereto.

The second transistor T2 may be turned on by a first gate signal of the first gate line GWL to electrically connect the data line DL with the first node N1, which is the first electrode of the first transistor T1. The second transistor T2 may be turned on in response to the first gate signal to apply data voltage to the first node N1. The gate electrode of the second transistor T2 may be connected to the first gate line GWL, the first electrode of the second transistor T2 may be connected to the data line DL, and the second electrode of the second transistor T2 may be connected to the first node N1. The second electrode of the second transistor T2 may be electrically connected to the first electrode of the first transistor T1, the second electrode of the fifth transistor T5 and the second electrode of the eighth transistor T8 through the first node N1. For example, the first electrode of the second transistor T2 may be the source electrode while the second electrode may be the drain electrode. It is, however, to be understood that the disclosure is not limited thereto.

The third transistor T3 may be turned on by a second gate signal of the second gate line GCL and may electrically connect a second node N2 which is the second electrode of the first transistor T1 with a third node N3 which is the gate electrode of the first transistor T1. The gate electrode of the third transistor T3 may be connected to the second gate line GCL, the first electrode of the third transistor T3 may be connected to the second node N2, and the second electrode of the third transistor T3 may be connected to the third node N3. The first electrode of the third transistor T3 may be electrically connected to the second electrode of the first transistor T1 and the first electrode of the sixth transistor T6 through the second node N2. The second electrode of the third transistor T3 may be electrically connected to the gate electrode of the first transistor T1, the first electrode of the fourth transistor T4, and the first capacitor electrode of the capacitor C1 through the third node N3. For example, the first electrode of the third transistor T3 may be the drain electrode while the second electrode may be the source electrode. It is, however, to be understood that the disclosure is not limited thereto.

The fourth transistor T4 may be turned on by a third gate signal of the third gate line GIL to electrically connect the third node N3 which is the gate electrode of the first transistor T1 with the first initialization voltage line VIL1. As the fourth transistor T4 is turned on based on the third gate signal, the gate electrode of the first transistor T1 may be initialized to the first initialization voltage. The gate electrode of the fourth transistor T4 may be connected to the third gate line GIL, the first electrode of the fourth transistor T4 may be connected to the third node N3, and the second electrode of the fourth transistor T4 may be connected to the first initialization voltage line VIL1. The first electrode of the fourth transistor T4 may be electrically connected to the gate electrode of the first transistor T1, the second electrode of the third transistor T3, and the first capacitor electrode of the capacitor C1 through the third node N3. For example, the first electrode of the fourth transistor T4 may be the drain electrode while the second electrode may be the source electrode. It is, however, to be understood that the disclosure is not limited thereto.

The fifth transistor T5 may be turned on by an emission signal of the emission control line EML and may electrically connect the driving voltage line VDL with the first node N1 which is the first electrode of the first transistor T1. A gate electrode of the fifth transistor T5 may be connected to the emission control line EML, a first electrode of the fifth transistor T5 may be connected to the supply voltage line VDL, and a second electrode of the fifth transistor T5 may be connected to the first node N1. The second electrode of the fifth transistor T5 may be electrically connected to the first electrode of the first transistor T1, the second electrode of the second transistor T2 and the second electrode of the eighth transistor T8 through the first node N1. For example, the first electrode of the fifth transistor T5 may be the source electrode while the second electrode may be the drain electrode. It is, however, to be understood that the disclosure is not limited thereto.

The sixth transistor T6 may be turned on by the emission signal of the emission control line EML to electrically connect the second node N2 which is the second electrode of the first transistor T1 with the fourth node N4 which is the first electrode of the light-emitting element ED. The gate electrode of the sixth transistor T6 may be connected to the emission control line EML, the first electrode of the sixth transistor T6 may be connected to the second node N2, and the second electrode of the sixth transistor T6 may be connected to the fourth node N4. The first electrode of the sixth transistor T6 may be electrically connected to the second electrode of the first transistor T1 and the first electrode of the third transistor T3 through the second node N2. The second electrode of the sixth transistor T6 may be electrically connected to the first electrode of the light-emitting element ED and the first electrode of the seventh transistor T7 through the fourth node N4. For example, the first electrode of the sixth transistor T6 may be the source electrode while the second electrode may be the drain electrode. It is, however, to be understood that the disclosure is not limited thereto.

In case that all of the fifth transistor T5, the first transistor T1 and the sixth transistor T6 are turned on, the driving current Isd may be supplied to the light-emitting element ED.

The seventh transistor T7 may be turned on by a fourth gate signal of the fourth gate line GBL to electrically connect the second initialization voltage line VIL2 with the fourth node N4 which is the first electrode of the light-emitting element ED. As the seventh transistor T7 is turned on based on the fourth gate signal, the first electrode of the light-emitting element ED may be initialized to the second initialization voltage. The second initialization voltage of the second initialization voltage line VIL2 may be different from the first initialization voltage of the first initialization voltage line VIL1. For another example, the second initialization voltage may be substantially equal to the first initialization voltage. The gate electrode of the seventh transistor T7 may be connected to the fourth gate line GBL, the first electrode of the seventh transistor T7 may be connected to the fourth node N4, and the second electrode of the seventh transistor T7 may be connected to the second initialization voltage line VIL2. The first electrode of the seventh transistor T7 may be electrically connected to the first electrode of the light-emitting element ED and the second electrode of the sixth transistor T6 through the fourth node N4. For example, the first electrode of the seventh transistor T7 may be the source electrode while the second electrode may be the drain electrode. It is, however, to be understood that the disclosure is not limited thereto.

The eighth transistor T8 may be turned on by the fourth gate signal of the fourth gate line GBL to electrically connect the bias voltage line VBL to the first node N1 which is the first electrode of the first transistor T1. The gate electrode of the eighth transistor T8 may be connected to the fourth gate line GBL, the first electrode of the eighth transistor T8 may be connected to the bias voltage line VBL, and the second electrode of the eighth transistor T8 may be connected to the first node N1. The second electrode of the eighth transistor T8 may be electrically connected to the first electrode of the first transistor T1, the second electrode of the second transistor T2 and the second electrode of the fifth transistor T5 through the first node N1. For example, the first electrode of the eighth transistor T8 may be the source electrode while the second electrode may be the drain electrode. It is, however, to be understood that the disclosure is not limited thereto. In another example, the eighth transistor T8 may be eliminated.

Each of the first transistor T1, the second transistor T2, the fifth transistor T5, the sixth transistor T6, the seventh transistor T7 and the eighth transistor T8 may include a silicon-based semiconductor region. For example, each of the first transistor T1, the second transistor T2, the fifth transistor T5, the sixth transistor T6, the seventh transistor T7 and the eighth transistor T8 may include a semiconductor region made of low-temperature polycrystalline silicon (LTPS). The semiconductor region made of low-temperature polycrystalline silicon may have a high electron mobility and excellent turn-on characteristics. Therefore, the display device 10 includes the first transistor T1, the second transistor T2, the fifth transistor T5, the sixth transistor T6, the seventh transistor T7 and the eighth transistor T8 having excellent turn-on characteristics, so that the pixels SP may be driven stably and efficiently.

Each of the first transistor T1, the second transistor T2, the fifth transistor T5, the sixth transistor T6, the seventh transistor T7 and the eighth transistor T8 may be a p-type transistor. For example, each of the first transistor T1, the second transistor T2, the fifth transistor T5, the sixth transistor T6, the seventh transistor T7 and the eighth transistor T8 may output the current introduced from the first electrode via the second electrode based on a gate-low voltage applied to the gate electrode.

The third transistor T3 and the fourth transistor T4 may include an oxide-based semiconductor region. For example, each of the third transistor T3 and the fourth transistor T4 may have a coplanar structure in which a gate electrode is disposed above an oxide-based semiconductor region. A transistor having such a coplanar structure may have excellent leakage current characteristics and allows for low-frequency driving, thereby reducing power consumption. Accordingly, the display device 10 includes the third transistor T3 and the fourth transistor T4 having good leakage current characteristics, so that it is possible to prevent leakage current from flowing inside the pixels, and to maintain the voltage inside the pixels stably.

Each of the third transistor T3 and the fourth transistors T4 may be an n-type transistor. For example, the third transistor T3 and the fourth transistor T4 may output the current flowing into the first electrode to the second electrode based on a gate-low voltage applied to the gate electrode.

The capacitor C1 may be connected between the third node N3 which is the gate electrode of the first transistor T1 and the supply voltage line VDL. For example, the first capacitor electrode of the capacitor C1 may be connected to the third node N3, and the second capacitor electrode of the capacitor C1 may be connected to the supply voltage line VDL, so that the potential difference between the supply voltage line VDL and the gate electrode of the first transistor T1 may be held.

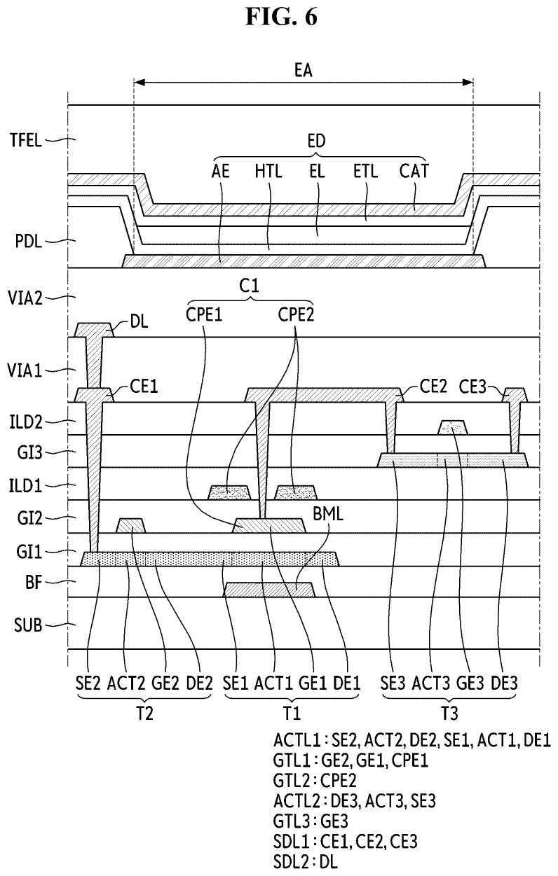

FIG. 6 is a schematic cross-sectional view showing a pixel in a display device according to an embodiment.

Referring to FIG. 6, a display panel 100 may include a substrate SUB, a metal layer BML, a buffer layer BF, a first active layer ACTL1, a first gate insulator GI1, a first gate layer GTL1, a second gate insulator GI2, a second gate layer GTL2, a first interlayer dielectric layer ILD1, a second active layer ACTL2, a third gate insulator GI3, a third gate layer GTL3, a second interlayer dielectric layer ILD2, a first source metal layer SDL1, a first via layer VIA1, a second source metal layer SDL2, a second via layer VIA2, a pixel-defining layer PDL, a light-emitting element ED, and an encapsulation layer TFEL.

The substrate SUB may be a base substrate or a base member. The substrate SUB may be a flexible substrate that is bendable, foldable, or rollable. For example, the substrate SUB may include a polymer resin such as polyimide PI. However, embodiments are not limited thereto. For another example, the substrate SUB may include a glass material or a metal material.

The metal layer BML may be disposed on the substrate SUB. The metal layer BML may overlap the semiconductor region ACT1 of the first transistor T1. The metal layer BML may be disposed under the first transistor T1 and may block electric field or static electricity applied to the first transistor T1.

The buffer layer BF may be disposed on the metal layer BML. For example, the buffer layer BF may include an inorganic film that prevents the permeation of air or moisture. For example, the buffer layer BF may include inorganic films stacked on one another alternately.

The first active layer ACTL1 may be disposed on the buffer layer BF. The first active layer ACTL1 may include a silicon-based material. For example, the first active layer ACTL1 may be made of low-temperature polycrystalline silicon (LTPS). The first active layer ACTL1 may include a semiconductor region ACT1, a first electrode SE1 and a second electrode DE1 of the first transistor T1, and a semiconductor region ACT2, a first electrode SE2 and a second electrode DE2 of the second transistor T2.

The first gate insulator GI1 may be disposed on the first active layer ACTL1. The first gate insulator GI1 may insulate the first active layer ACTL1 from the first gate layer GTL1.

The first gate layer GTL1 may be disposed on the first gate insulator GI1. The first gate layer GTL1 may include the gate electrode GE1 of the first transistor T1, the gate electrode GE2 of the second transistor T2, and the first capacitor electrode CPE1. The gate electrode GE1 of the first transistor T1 may be a portion of the first capacitor electrode CPE1, and the gate electrode GE2 of the second transistor T2 may be a portion of the first gate line GWL.

The second gate insulator GI2 may be disposed on the first gate layer GTL1. The second gate insulator GI2 may insulate the first gate layer GTL1 from the second gate layer GTL2.

The second gate layer GTL2 may be disposed on the second gate insulator GI2. The second gate layer GTL2 may include the second capacitor electrode CPE2. The second capacitor electrode CPE2 may overlap the first capacitor electrode CPE1. The capacitor C1 of FIG. 5 may include first and second capacitor electrodes CPE1 and CPE2.

The first interlayer dielectric layer ILD1 may be disposed on the second gate layer GTL2. The first interlayer dielectric layer ILD1 may insulate the second gate layer GTL2 from the second active layer ACTL2.

The second active layer ACTL2 may be disposed on the first interlayer dielectric layer ILD1. The second active layer ACTL2 may include an oxide-based material. The second active layer ACTL2 may include a semiconductor region ACT3, a first electrode DE3 and a second electrode SE3 of the third transistor T3.

The third gate insulator GI3 may be disposed on the second active layer ACTL2. The third gate insulator GI3 may insulate the second active layer ACTL2 from the third gate layer GTL3.

The third gate layer GTL3 may be disposed on the third gate insulator GI3. The third gate layer GTL3 may include a gate electrode GE3 of the third transistor T3. The gate electrode GE3 of the third transistor T3 may be a portion of the second gate line GCL.

The second interlayer dielectric layer ILD2 may be disposed on the third gate layer GTL3. The second interlayer dielectric layer ILD2 may insulate the third gate layer GTL3 from the first source metal layer SDL1.

The first source metal layer SDL1 may be disposed on the second interlayer dielectric layer ILD2. The first source metal layer SDL1 may include first to third connection electrodes CE1, CE2 and CE3. The first connection electrode CE1 may electrically connect the data line DL to the first electrode SE2 of the second transistor T2. The second connection electrode CE2 may electrically connect the first capacitor electrode CPE1 to the second electrode SE3 of the third transistor T3. The third connection electrode CE3 may electrically connect the first electrode DE3 of the third transistor T3 to the second electrode DEL1 of the first transistor T1.

The first via layer VIA1 may be disposed on the first source metal layer SDL1. The first via layer VIA1 may insulate the first source metal layer SDL1 from the second source metal layer SDL2. The first via layer VIA1 may have a flat upper surface. The first via layer VIA1 may include an organic insulating material such as polyimide (PI).

The second source metal layer SDL2 may be disposed on the first via layer VIAL. The second source metal layer SDL2 may include a data line DL.

The second via layer VIA2 may be disposed on the second source metal layer SDL2. The second via layer VIA2 may insulate the second source metal layer SDL2 from the pixel electrode AE. The second via layer VIA2 may have a flat upper surface. The second via layer VIA2 may include an organic insulating material such as polyimide (PI).

The pixel-defining layer PDL may be disposed on the second via layer VIA2. The pixel-defining layer PDL may define emission areas EA. The pixel-defining layer PDL may include an organic insulating material such as polyimide (PI).

The light-emitting element ED may include a pixel electrode AE, a hole transport layer HTL, an emissive layer EL, an electron transport layer ETL, and a common electrode CAT. The pixel electrode AE may be disposed on the second via layer VIA2. The pixel electrode AE may overlap one of the emission areas EA defined by the pixel-defining layer PDL. The pixel electrode AE may receive a driving current from the pixel circuit of the pixel SP.

The hole transport layer HTL may be disposed on the pixel electrode AE in the emission area EA and may be disposed on the pixel-defining layer PDL in the non-emission area. The hole transport layer HTL may not be separately disposed in each of the pixels SP but may be implemented as a common layer across all of the pixels SP.

The emissive layer EL may be disposed on the hole transport layer HTL in the emission area EA. For example, the emissive layer EL may be an organic emissive layer made of an organic material. However, embodiments are not limited thereto.

The electron transport layer ETL may be disposed on the emissive layer EL in the emission area EA and may be disposed on the hole transport layer HTL in the non-emission area. The electron transport layer ETL may not be separately disposed in each of the pixels SP but may be implemented as a common layer across all of the pixels SP.

The common electrode CAT may be disposed on the electron transport layer ETL. For example, the common electrode CAT may extend across all of the pixels SP. The common electrode CAT may be a transparent electrode and may transmit light. The common electrode CAT may be electrically connected to the low-level voltage line VSL and may receive a low-level voltage, a common voltage, or a cathode voltage.

In case that the emissive layer EL is an organic light-emitting layer, in case that the pixel circuit of the pixel SP applies a selected voltage to the pixel electrode AE and the common electrode CAT receives a common voltage or cathode voltage, holes may move (or transfer) to the emissive layer EL through the hole transport layer HTL and electrons may move (or transfer) to the emissive layer EL through the electron transport layer ETL, and they may combine in the emissive layer EL to emit light.

The encapsulation layer TFEL may be disposed on the common electrode CAT to cover the light-emitting elements ED. The encapsulation layer TFEL may include at least one inorganic film to prevent permeation of oxygen or moisture into the light-emitting elements ED. The encapsulation layer TFEL may include at least one organic film to protect the light-emitting elements ED from particles such as dust.

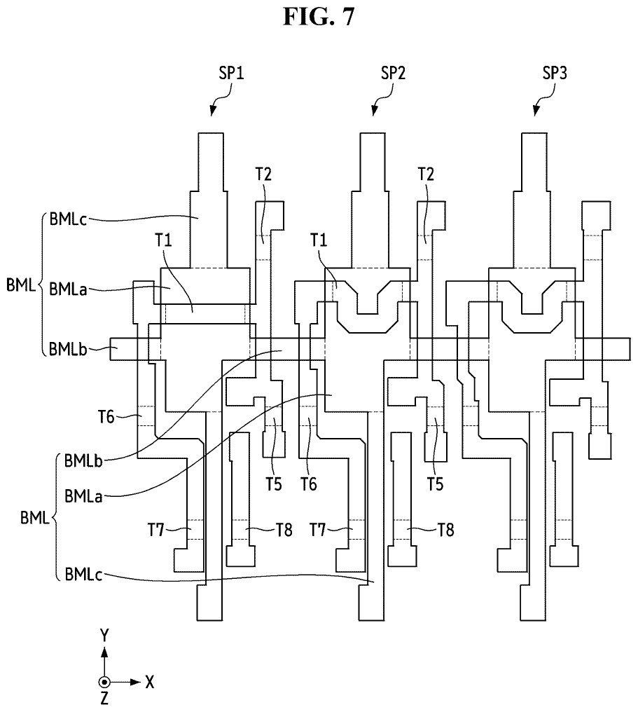

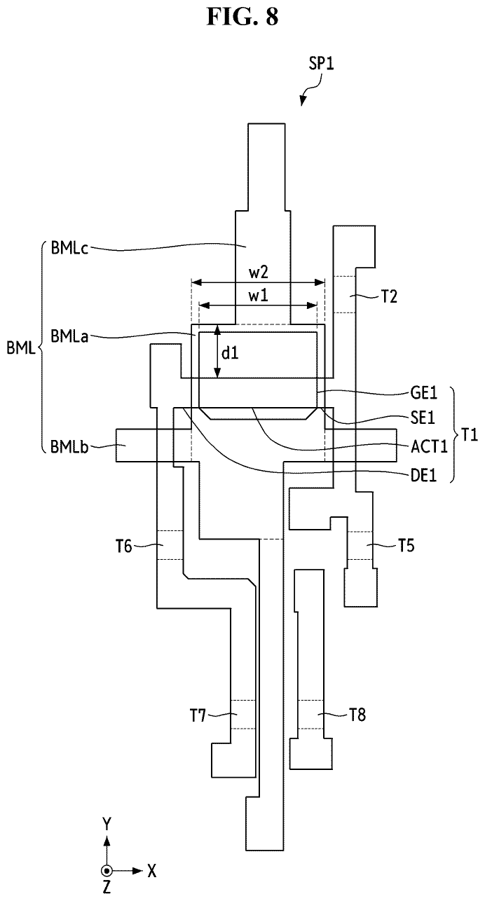

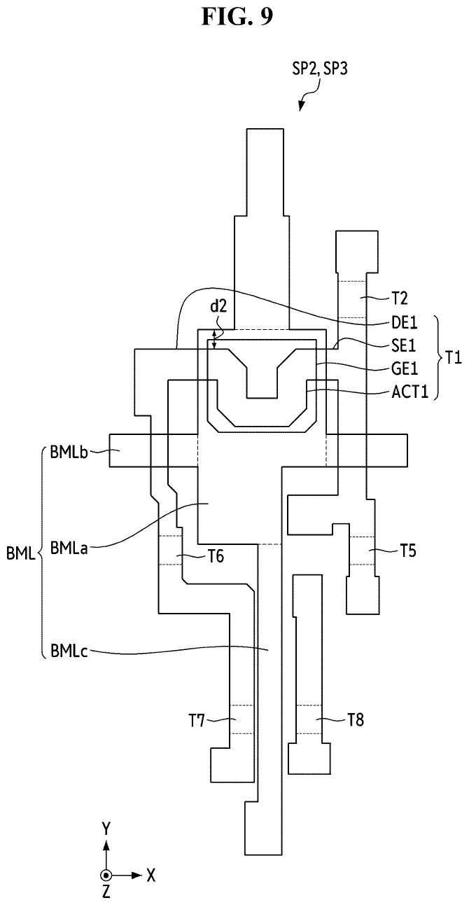

FIG. 7 is a schematic plan view showing metal layers and first active layers of first to third pixels in a display device according to an embodiment. FIG. 8 is a schematic plan view showing a metal layer, a first active layer and a first gate layer of the first pixel in the display device according to the embodiment. FIG. 9 is a schematic plan view showing a metal layer, a first active layer and a first gate layer of each of the second and third pixels in the display device according to the embodiment.

Referring to FIGS. 7 to 9, a metal layer BML may include first to third portions BMLa, BMLb and BMLc. The first portion BMLa of the metal layer BML may overlap a first transistor T1 of each of the first to third pixels SP1, SP2 and SP3. The first portion BMLa of the metal layer BML may be disposed under the first transistor T1 to block electric field or static electricity applied to the first transistor T1.

The second portion BMLb of the metal layer BML may extend in the x-axis direction to connect the first portion BMLa to another adjacent one in the x-axis direction. The third portion BMLc of the metal layer BML may extend in the y-axis direction to connect the first portion BMLa to another adjacent one in the y-axis direction. The first portion BMLa of the metal layer BML may have a larger width than the second portion BMLb in the y-direction, and may have a larger width than the third portion BMLc in the x-direction. The first portion BMLa of the metal layer BML may have a relatively large area to block an electric field or static electricity applied to the first transistor T1, and the second and third portions BMLb and BMLc may have thin and long shapes to connect between the first portions BMLa.

The pixel SP may include first to third pixels SP1, SP2 and SP3 that emit light of different colors. For example, the first pixel SP1 may emit blue light, the second pixel SP2 may emit red light, and the third pixel SP3 may emit green light, but embodiments are not limited thereto. Each of the first to third pixels SP1, SP2 and SP3 may include the first to eighth transistors T1, T2, T3, T4, T5, T6, T7 and T8 and the capacitor C1 shown in FIG. 5. The first transistor T1, the second transistor T2, the fifth transistor T5, the sixth transistor T6, the seventh transistor T7 and the eighth transistor T8 of the first to third pixels SP1, SP2 and SP3 may be disposed in the first active layer ACTL1. The metal layer BML in each of the first to third pixels SP1, SP2 and SP3 may have the same shape, but embodiments are not limited thereto.

A semiconductor region ACT1 of the first transistor T1 of the first pixel SP1 may have a straight line shape extending in the x-axis direction. The semiconductor region ACT1 of the first transistor T1 of each of the second and third pixels SP2 and SP3 may have a shape that is bent at least once. The semiconductor region ACT1 of the first transistor T1 of each of the second and third pixels SP2 and SP3 may have a U-shape. However, embodiments are not limited thereto. The semiconductor region ACT1 of the first transistor T1 of each of the first to third pixels SP1, SP2 and SP3 may be disposed between the metal layer BML and the gate electrode GE1, and may overlap the metal layer BML and the gate electrode GE1.

The semiconductor region ACT1 of the first transistor T1 of the first pixel SP1 may be adjacent to the central portion of the first portion BMLa of the metal layer BML and may be spaced apart from the upper side of the first portion BMLa of the metal layer BML by a selected distance. The semiconductor region ACT1 of the first transistor T1 of the first pixel SP1 may be closer to the lower edge portion than the upper edge portion of the gate electrode GE1 of the first transistor T1. The central portion of the semiconductor region ACT1 of the first transistor T1 of the first pixel SP1 may be spaced from an edge portion of the first portion BMLa of the metal layer BML. A first distance d1 between the semiconductor region ACT1 of the first transistor T1 of the first pixel SP1 and the upper side of the first portion BMLa of the metal layer BML may be greater than a second distance d2 between the semiconductor region ACT1 of the first transistor T1 of the second or third pixel SP2 or SP3 and the upper side of the first portion BMLa of the metal layer BML. For example, the second distance d2 may be substantially equal to the distance between the uppermost portion of the semiconductor region ACT1 of the first transistor T1 of the second or third pixel SP2 or SP3 and the upper side of the first portion BMLa of the metal layer BML. For example, the first distance d1 may be substantially equal to or greater than twice the second distance d2.

The central portion of the semiconductor region ACT1 of the first transistor T1 of the first pixel SP1 may be spaced apart from the edge portion of the first portion BMLa of the metal layer BML, so that the display device 10 may block electric field and static electricity applied to the first transistor T1 of the first pixel SP1 and may improve the issue of afterimage.

The first width w1 of the gate electrode GE1 of the first transistor T1 of the first pixel SP1 in the x-axis direction may be smaller than the second width w2 of the first portion BMLa of the metal layer BML in the x-axis direction. The entire semiconductor region ACT1 of the first transistor T1 of the first pixel SP1 may be shielded by the metal layer BML. The metal layer BML may block electric field and static electricity applied to the first transistor T1 by shielding a relatively large area of the semiconductor region ACT1 of the first transistor T1, thereby improving the issue of afterimage.

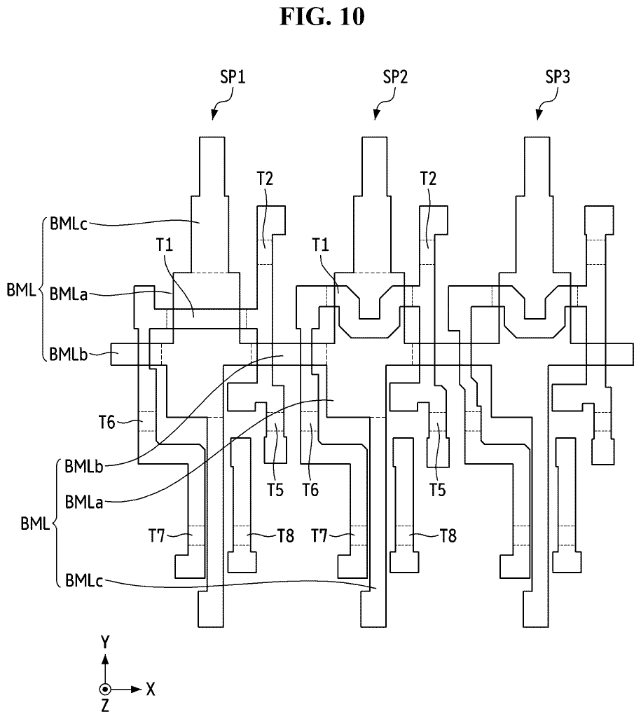

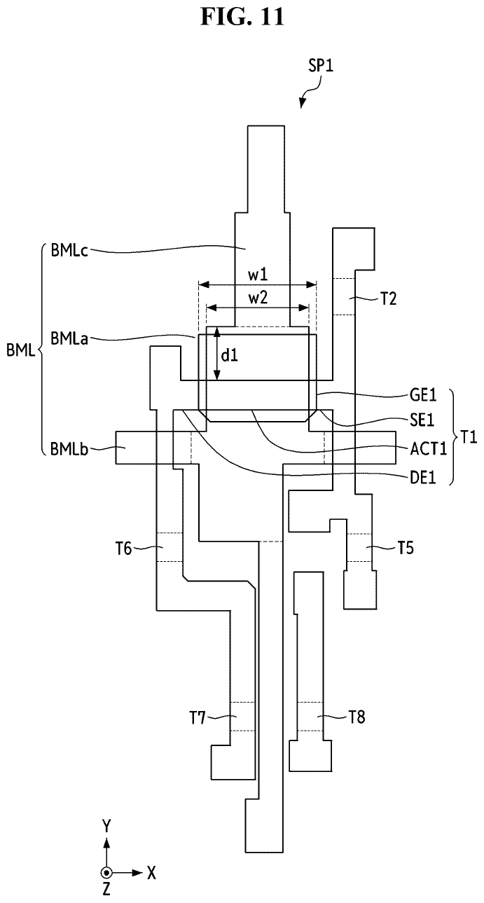

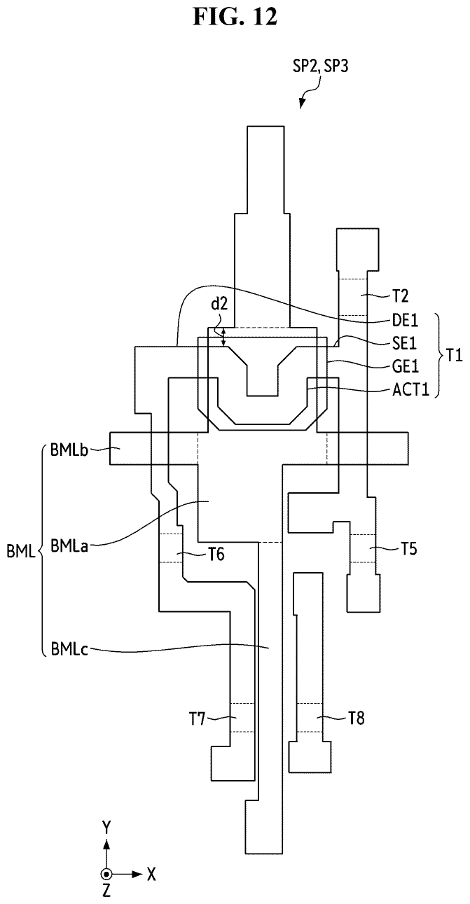

FIG. 10 is a schematic plan view showing metal layers and first active layers of first to third pixels in a display device according to another embodiment. FIG. 11 is a schematic plan view showing a metal layer, a first active layer and a first gate layer of the first pixel in the display device according to the another embodiment. FIG. 12 is a schematic plan view showing a metal layer, a first active layer and a first gate layer of each of the second and third pixels in the display device according to the another embodiment. The display device of FIGS. 10 to 12 is substantially identical or similar to the display device of FIGS. 7 to 9 except for the shape of a metal layer BML and, therefore, the redundant description will be omitted for descriptive convenience.

Referring to FIGS. 10 to 12, a metal layer BML may include first to third portions BMLa, BMLb and BMLc. The first portion BMLa of the metal layer BML may overlap a first transistor T1 of each of the first to third pixels SP1, SP2 and SP3. The first portion BMLa of the metal layer BML may be disposed under the first transistor T1 to block electric field or static electricity applied to the first transistor T1.

The second portion BMLb of the metal layer BML may extend in the x-axis direction to connect the first portion BMLa to another adjacent one in the x-axis direction. The third portion BMLc of the metal layer BML may extend in the y-axis direction to connect the first portion BMLa to another adjacent one in the y-axis direction. The first portion BMLa of the metal layer BML may have a larger width than the second portion BMLb in the y-direction, and may have a larger width than the third portion BMLc in the x-direction. The first portion BMLa of the metal layer BML may have a relatively large area to block an electric field or static electricity applied to the first transistor T1, and the second and third portions BMLb and BMLc may have thin and long shapes to connect between the first portions BMLa.

The pixel SP may include first to third pixels SP1, SP2 and SP3 that emit light of different colors. For example, the first pixel SP1 may emit blue light, the second pixel SP2 may emit red light, and the third pixel SP3 may emit green light, but the disclosure is not limited thereto. Each of the first to third pixels SP1, SP2 and SP3 may include the first to eighth transistors T1, T2, T3, T4, T5, T6, T7 and T8 and the capacitor C1 shown in FIG. 5. The first transistor T1, the second transistor T2, the fifth transistor T5, the sixth transistor T6, the seventh transistor T7 and the eighth transistor T8 of the first to third pixels SP1, SP2 and SP3 may be disposed in the first active layer ACTL1. The metal layer BML in each of the first to third pixels SP1, SP2 and SP3 may have the same shape, but the disclosure is not limited thereto.

A semiconductor region ACT1 of the first transistor T1 of the first pixel SP1 may have a straight line shape extending in the x-axis direction. The semiconductor region ACT1 of the first transistor T1 of each of the second and third pixels SP2 and SP3 may have a shape that is bent at least once. The semiconductor region ACT1 of the first transistor T1 of each of the second and third pixels SP2 and SP3 may have a U-shape. However, embodiments are not limited thereto. The semiconductor region ACT1 of the first transistor T1 of each of the first to third pixels SP1, SP2 and SP3 may be disposed between the metal layer BML and the gate electrode GE1, and may overlap the metal layer BML and the gate electrode GEL.

The semiconductor region ACT1 of the first transistor T1 of the first pixel SP1 may be adjacent to the central portion of the first portion BMLa of the metal layer BML and may be spaced apart from the upper side of the first portion BMLa of the metal layer BML by a selected distance. The semiconductor region ACT1 of the first transistor T1 of the first pixel SP1 may be closer to the lower edge portion than the upper edge portion of the gate electrode GE1 of the first transistor T1. The central portion of the semiconductor region ACT1 of the first transistor T1 of the first pixel SP1 may be spaced from an edge portion of the first portion BMLa of the metal layer BML. A first distance d1 between the semiconductor region ACT1 of the first transistor T1 of the first pixel SP1 and the upper side of the first portion BMLa of the metal layer BML may be greater than a second distance d2 between the semiconductor region ACT1 of the first transistor T1 of the second or third pixel SP2 or SP3 and the upper side of the first portion BMLa of the metal layer BML. For example, the second distance d2 may be substantially equal to the distance between the uppermost portion of the semiconductor region ACT1 of the first transistor T1 of the second or third pixel SP2 or SP3 and the upper side of the first portion BMLa of the metal layer BML. For example, the first distance d1 may be substantially equal to or greater than twice the second distance d2.

The central portion of the semiconductor region ACT1 of the first transistor T1 of the first pixel SP1 may be spaced apart from the edge portion of the first portion BMLa of the metal layer BML, so that the display device 10 may block electric field and static electricity applied to the first transistor T1 of the first pixel SP1 and may improve the issue of afterimage.

The first width w1 of the gate electrode GE1 of the first transistor T1 of the first pixel SP1 in the x-axis direction may be greater than the second width w2 of the first portion BMLa of the metal layer BML in the x-axis direction. Most of the semiconductor region ACT1 of the first transistor T1 of the first pixel SP1 may be shielded by the metal layer BML, but the edge portions of the semiconductor region ACT1 may not be shielded by the metal layer BML. As the area of the semiconductor region ACT1 that is not shielded by the metal layer BML increases, the introduction of electric field, static electricity, or internal light applied to the semiconductor region ACT1 may increase. The metal layer BML may block electric field and static electricity applied to the first transistor T1 by partially shielding the semiconductor region ACT1 of the first transistor T1, thereby improving the issue of afterimage. As the metal layer BML does not shield the edge portions of the semiconductor region ACT1 of the first transistor T1, it is possible to improve the issue of afterimage by increasing the introduction of internal light into the semiconductor region ACT1.

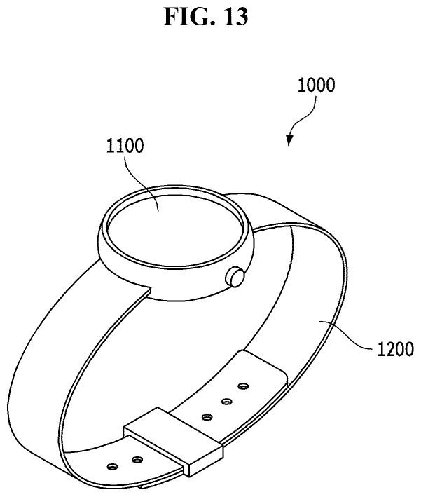

Referring to FIG. 13, the electronic device may be applied to a smart watch 1000 including a display part 1100 and a strap part 1200.

The smart watch 1000 may be a wearable electronic device. For example, the smart watch 1000 may have a structure in which the strap part 1200 is mounted on a wrist of a user. The electronic device may be applied to the display part 1100, so that image data including time information can be provided to the user.

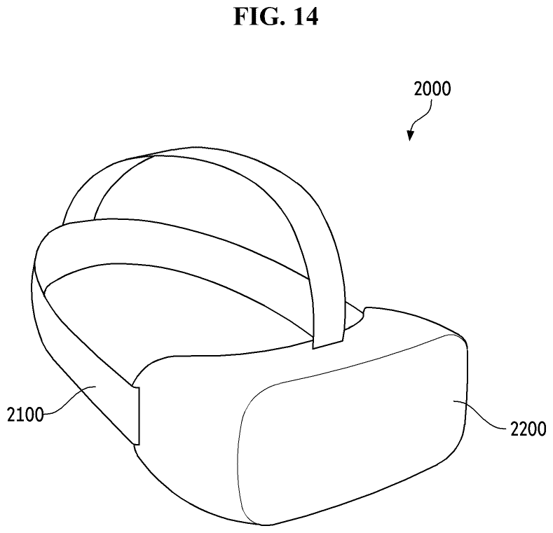

Referring to FIG. 14, the electronic device may be applied to a head mounted display device 2000.

The head mounted display device 2000 may be a wearable electronic device which can be worn on the head of a user. For example, the head mounted display device 2000 may be a wearable device for virtual reality (VR) or mixed reality (MR). The head mounted display device 2000 may include a head mounted band 2100 and a display accommodating case 2200. The head mounted band 2100 may be connected to the display accommodating case 2200. The head mounted band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments are not limited thereto. For example, the head mounted band 2100 may be implemented in the form of a glasses frame, a helmet or the like within the spirit and the scope of the disclosure. For example, the electronic device may be at least one of televisions, notebook computers, monitors, advertisement boards, Internet of things (IoTs), portable electronic apparatuses including mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays (HMDs), instrument panels for automobiles, center fascias for automobiles, or center information displays (CIDs) on a dashboard, room mirror displays of automobiles, and displays of an entertainment system on a backside of front seats in automobiles.

The above description is an example of technical features of the disclosure, and those skilled in the art to which the disclosure pertains will be able to make various modifications and variations. Therefore, the embodiments of the disclosure described above may be implemented separately or in combination with each other.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a first pixel comprising:
a first light-emitting element emitting light of a first color, and
a first transistor that provides a driving current to the first light-emitting element and comprising a semiconductor region extending in a first direction;
a second pixel comprising:
a second light-emitting element emitting light of a second color different from the first color, and
a second transistor that provides a driving current to the second light-emitting element and comprising a semiconductor region;
a first metal layer disposed under the first transistor and overlapping the semiconductor region of the first transistor; and
a second metal layer disposed under the second transistor and overlapping the semiconductor region of the second transistor,
wherein a first distance between a first side of the first metal layer and the semiconductor region of the first transistor in a second direction intersecting the first direction is greater than a second distance between a first side of the second metal layer corresponding to the first side of the first metal layer and the semiconductor region of the second transistor.

2. The display device of claim 1, wherein
the semiconductor region of the first transistor has a straight line shape extending in the first direction, and
the semiconductor region of the second transistor has a shape that is bent at least once.

3. The display device of claim 1, wherein the first distance is substantially equal to or greater than twice the second distance.

4. The display device of claim 1, wherein
the first color is blue, and
the second color is red or green.

5. The display device of claim 1, wherein the first metal layer comprises:
a first portion overlapping the semiconductor region of the first transistor;
a second portion extending from the first portion in the first direction and connected to the second metal layer; and
a third portion extending from the first portion in the second direction.

6. The display device of claim 5, wherein a first width of a gate electrode of the first transistor in the first direction is smaller than a second width of the first portion of the first metal layer in the first direction.

7. The display device of claim 6, wherein the entire semiconductor region of the first transistor overlaps the first portion of the first metal layer.

8. The display device of claim 5, wherein a first width of a gate electrode of the first transistor in the first direction is greater than a second width of the first portion of the first metal layer in the first direction.

9. The display device of claim 8, wherein
a central portion of the semiconductor region of the first transistor overlaps the first portion of the first metal layer, and
edge portions of the semiconductor region of the first transistor does not overlap the first metal layer.

10. The display device of claim 1, wherein the first pixel further comprises:
a third transistor that applies a data voltage to a first electrode of the first transistor;
a fourth transistor that electrically connects a second electrode of the first transistor to a gate electrode of the first transistor;
a fifth transistor that electrically connects the gate electrode of the first transistor to a first initialization voltage line; and
a capacitor connected between a driving voltage line supplying a driving voltage and the gate electrode of the first transistor.

11. The display device of claim 10, further comprising:
a first active layer disposed on the first metal layer and comprising a semiconductor region of the first transistor;
a first gate layer disposed on the first active layer and comprising a first capacitor electrode of the capacitor;
a second gate layer disposed on the first gate layer and comprising a second capacitor electrode of the capacitor;
a second active layer disposed on the second gate layer and comprising a semiconductor region of the fourth transistor; and
a third gate layer disposed on the second active layer and comprising a gate electrode of the fourth transistor.

12. An electronic device comprising: a display device,
wherein the display device comprises:
a first pixel comprising:
a first light-emitting element, and
a first transistor that provides a driving current to the first light-emitting element and comprising a semiconductor region;
a second pixel comprising:
a second light-emitting element, and
a second transistor that provides a driving current to the second light-emitting element and comprising a semiconductor region;
a first metal layer disposed under the first transistor and overlapping the semiconductor region of the first transistor; and
a second metal layer disposed under the second transistor and overlapping the semiconductor region of the second transistor,
wherein the semiconductor region of the first transistor is closer to a lower edge portion than an upper edge portion of a gate electrode of the first transistor.

13. The electronic device of claim 12, wherein
the semiconductor region of the first transistor has a straight line shape extending in a first direction, and
the semiconductor region of the second transistor has a shape that is bent at least once.

14. The electronic device of claim 13, wherein a first distance between an upper side of the first metal layer and the semiconductor region of the first transistor in a second direction intersecting the first direction is greater than a second distance between an upper side of the second metal layer and the semiconductor region of the second transistor in the second direction.

15. The electronic device of claim 14, wherein the first metal layer comprises:
a first portion overlapping the semiconductor region of the first transistor;
a second portion extending from the first portion in the first direction and connected to the second metal layer; and
a third portion extending from the first portion in the second direction.

16. The electronic device of claim 15, wherein a first width of a gate electrode of the first transistor in the first direction is smaller than a second width of the first portion of the first metal layer in the first direction.

17. The electronic device of claim 16, wherein the entire semiconductor region of the first transistor overlaps the first portion of the first metal layer.

18. The electronic device of claim 15, wherein a first width of a gate electrode of the first transistor in the first direction is greater than a second width of the first portion of the first metal layer in the first direction.

19. The electronic device of claim 18, wherein
a central portion of the semiconductor region of the first transistor overlaps the first portion of the first metal layer, and
edge portions of the semiconductor region of the first transistor does not overlap the first metal layer.

20. The electronic device of claim 12, wherein
the first light-emitting element emits blue light, and
the second light-emitting element emits red light or green light.
